(19) United States
(12) Patent Application Publication
(10) Pub. No.: US 2025/0038742 A1
(43) Pub. Date: Jan. 30, 2025

(54) PWM CIRCUIT, APPARATUS INCLUDING THE SAME

(71) Applicant: LAPIS Technology Co., Ltd., Yokohama-shi (JP)

(72) Inventor: Daisuke NIHEI, Kanagawa (JP)

(21) Appl. No.: 18/785,646

(22) Filed: Jul. 26, 2024

(30) Foreign Application Priority Data
Jul. 26, 2023 (JP) 2023-122014

(51) Int. Cl. H03K 7/08

(52) U.S. Cl. CPC H03K 7/08

(57) ABSTRACT

A PWM circuit includes: a PWM signal generation circuit including a counter circuit and an output control circuit and configured to generate a PWM control signal; a first control circuit configured to generate a first control signal in response to a first external trigger signal; and a second control circuit configured to generate a second control signal in response to a second external trigger signal. The PWM signal generation circuit is configured to start the operation of the counter circuit in association with the first control signal from the first control circuit, and the PWM signal generation circuit includes a first circuit configured to perform PWM control in response to the second control signal from the second control circuit.

### CROSS-REFERENCE TO RELATED APPLICATION

This application is based on and claims priority under 35 USC 119 from Japanese Patent Application No. 2023-122014 filed on Jul. 26, 2023, the disclosure of which are incorporated herein by reference.

### BACKGROUND

### Technical Field

The present disclosure relates to a pulse width modulation circuit, an apparatus including a trigger circuit, and an apparatus including a PWM circuit.

### Related Art

Japanese Patent Application Laid-Open (JP-A) No. 2011-193181 discloses a pulse width modulation signal generation circuit, and this circuit provides a pulse width modulation signal which is not affected by switching noise and is independent of the initial setting of the operation of circuit and the setting of duty.

### SUMMARY

A method for performing a pulse width modulation (hereinafter referred to as PWM) control using a microcomputer uses the function of edge and level controls. In the edge control, the microcomputer determines the start and end of the PWM control in response to an external trigger signal, which may include a vibrating waveform, i.e., chattering. What is needed in the PWM control is to reduce the influence of chattering.

A PWM circuit according to a first aspect of the present disclosure includes: a PWM signal generation circuit configured to generate a PWM control signal and including a counter circuit and an output control circuit; and multiple control circuits configured to control the PWM signal generation circuit at at least one of the timings of start and end of a PWM control, wherein the multiple control circuits include a first control circuit configured to generate a first control signal in response to a first external trigger signal and to control the PWM signal generation circuit at the timing of start of the PWM control, wherein the multiple control circuits include a second control circuit configured to generate a second control signal in response to a second external trigger signal and to control the PWM signal generation circuit at one of the timings of start and end of the PWM control, and wherein the PWM signal generation circuit is configured to start the operation of the counter circuit in association with the first control signal. The PWM signal generation circuit includes at least one of first, second, and third circuits as follows: the first circuit is configured to perform the PWM control in response to the first control signal and the second control signal when the first control circuit is configured to control the operation of the PWM signal generation circuit at the timing of start of the PWM control and the second control circuit is configured to determine the operation of the PWM signal generation circuit at the timing of end of the PWM control; the second circuit is configured to put the counter circuit into an output disabled state in a first period of the second control signal when the first and second control circuits are configured to control the operation of the PWM signal generation circuit at the timing of start of the PWM control, a third control circuit of the multiple control circuits determines the operation of the PWM signal generation circuit at the timing of end of the PWM control, and the third control circuit is different from the first and second control circuits; and the third circuit is configured to put the output control circuit into an output disabled state in the first period of the second control signal when the first and second control circuits are configured to control the operation of the PWM signal generation circuit at the timing of start of the PWM control and the third control circuit is configured to control the operation of the PWM signal generation circuit at the timing of end of the PWM control.

A PWM circuit according to a second aspect of the present disclosure includes: a PWM signal generation circuit configured to generate a PWM control signal and including a counter circuit; and multiple control circuits configured to control the PWM signal generation circuit, wherein the multiple control circuits include a first control circuit, wherein the first control circuit is configured to receive a first external trigger signal as an input signal to generate a first control signal in response to a first transition of the input signal without responding to the subsequent change of the input signal, and wherein the PWM signal generation circuit is configured to start a PWM control in response to the first control signal and to allow the counter circuit to operate in response to the first control signal.

A PWM circuit according to a third aspect of the present disclosure includes: a PWM signal generation circuit configured to generate a PWM control signal and including a counter circuit and an output control circuit; and multiple control circuits configured to control the PWM signal generation circuit, wherein the multiple control circuits include a first control circuit and a second control circuit, wherein the first control circuit is configured to generate a first control signal in response to a first external trigger signal, wherein the PWM signal generation circuit is configured to start a PWM control in response to the first control signal, wherein the second control circuit is configured to generate a second control signal in response to a second external trigger signal at the timing of start of the PWM control, and wherein the PWM signal generation circuit is operable in response to the second control signal to put at least one of the output control circuit and the counter circuit into an output disabled state during a first period of the second control signal and to provide the PWM control signal after the first period of the second control signal.

An apparatus according to a fourth aspect of the present disclosure includes: a PWM circuit according to the first aspect, the PWM circuit being incorporated in a microcomputer; and one or more trigger circuits configured to being electrically coupled to the PWM circuit and to generate at least one of the first and second external trigger signal, the trigger circuits being outside the microcomputer.

An apparatus according to a fifth aspect of the present disclosure includes: a PWM circuit according to the first aspect, the PWM circuit being incorporated in a microcomputer; and a device configured to being electrically coupled to the PWM circuit to operate in response to the PWM control signal, the device being outside the microcomputer.

### BRIEF DESCRIPTION OF THE DRAWINGS

Exemplary embodiments of the present disclosure will be described in detail based on the following figures, wherein:

FIG. 1 is a schematic diagram showing a PWM circuit according to the present disclosure;

FIG. 2 is a schematic diagram showing an exemplary PWM circuit according to the present disclosure;

FIG. 3 is a diagram showing exemplary operating waveforms of major nodes of the PWM circuit shown in FIG. 2;

FIG. 4 is a schematic diagram showing an exemplary PWM circuit according to the present disclosure;

FIG. 5 is a diagram showing exemplary operating waveforms of major nodes of the PWM circuit shown in FIG. 4;

FIG. 6 is a schematic diagram showing an exemplary PWM circuit according to the present disclosure;

FIG. 7 is a diagram showing exemplary operating waveforms of major nodes of the PWM circuit shown in FIG. 6;

FIG. 8 is a block diagram showing a circuit which performs the operation of start/stop using the PWM control circuit;

FIG. 9 is a diagram showing exemplary operating waveforms of the PWM control circuit that operates to perform the controls of start and stop using software instructions;

FIG. 10 is a diagram showing exemplary operating waveforms of the PWM control circuit that operates to perform the controls of start and stop using the edge control in response to an external trigger signal;

FIG. 11 is a diagram showing exemplary operating waveforms of the PWM control circuit that operates to perform the start and stop controls using the level control;

FIG. 12 is a diagram showing exemplary operating waveforms of the PWM control circuit that receives an external trigger signal with chattering;

FIG. 13 is a block diagram showing a circuit which performs start/stop controls by a PWM control circuit in response to a signal sampled from an external trigger signal; and

FIG. 14 is a diagram showing exemplary operating waveforms in the control that uses a signal sampled from an external trigger signal.

### DETAILED DESCRIPTION

Hereinafter, embodiments for carrying out the present disclosure will be described with reference to the drawings. In the following description, the same and similar parts will be denoted by the same and similar reference numerals to omit duplicated description.

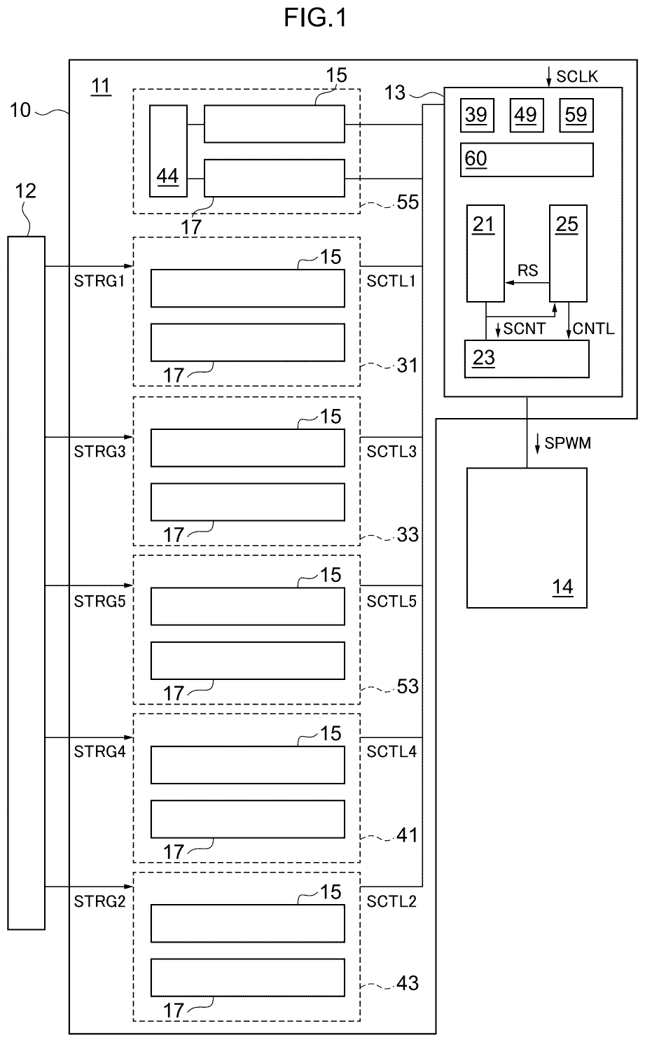

FIG. 1 is a schematic diagram showing a PWM circuit according to the present disclosure.

The PWM circuit 11 includes a PWM signal generation circuit 13 and multiple control circuits (31, 33, 41, 43, and 53). The PWM circuit 11 may be configured to operate in accordance with an edge control.

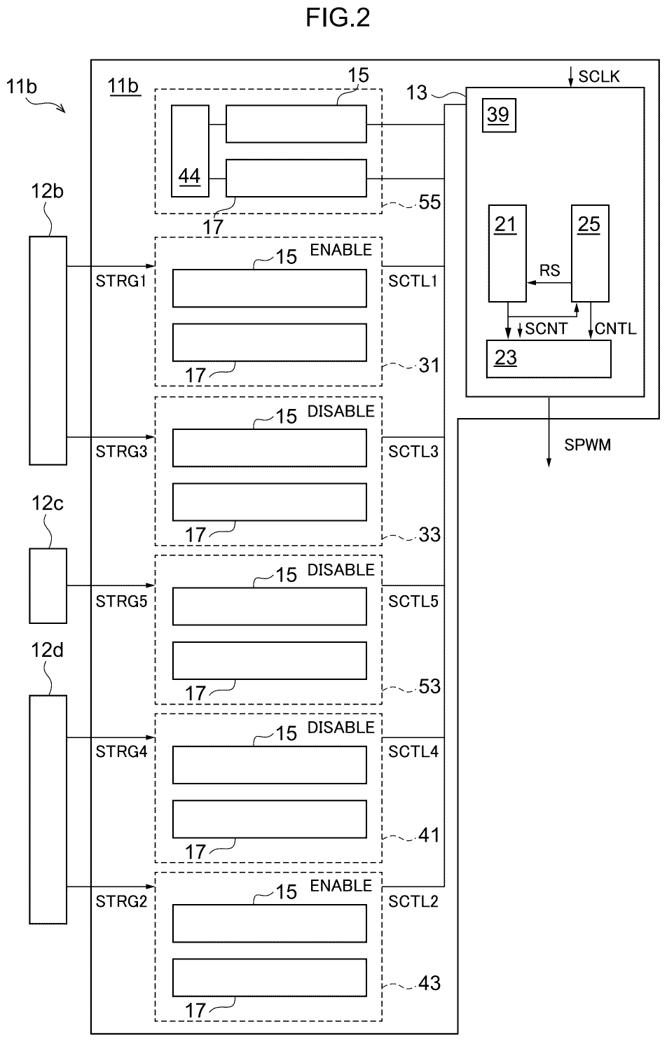

The exemplary PWM circuit 11 can be embedded in the microcomputer 10. The PWM circuit 11 can receive trigger signals from one or more trigger circuits 12 (12b, 12c, and 12d of FIG. 2), which are disposed outside the microcomputer 10. Referring to FIG. 1, the PWM circuit 11 can receive, for example, five trigger signals (STRG1, STRG2, STRG3, STRG4, and STRG5). The multiple control circuits (31, 33, 41, 43, and 53) each include one or more start control circuits and one or more stop control circuits. The start control circuits each are configured to control the start of a PWM control. The stop control circuits each are configured to control the termination of the PWM control. Specifically, an external trigger circuit alone may control a single start control circuit and a single stop control circuit. Further, an external trigger circuit alone may control a single control circuit, which can work as an independent control circuit to perform the control that is associated with the starting and ending of the PWM control. The start control circuit can be configured to respond to one of the rising and falling edges of an input signal, and independently of the start control circuit, the stop control circuit can be configured to respond to one of the rising and falling edges of an input signal.

In the control circuits (31, 33, 41, 43, and 53), the start control circuit may receive one external trigger signal from an external trigger circuit, and thereafter the stop control circuit may receive another external trigger signal. However, the two types of external trigger signals may be input to the PWM circuit 11 substantially simultaneously, and in that case, the external trigger signal of the stop control may be processed with priority over the external trigger signal of the start control.

The PWM signal generation circuit 13 is configured to create a PWM control signal SPWM, and the PWM control signal SPWM is supplied to a device to be controlled, which is hereinafter referred to as a controlled device 14. The PWM signal generation circuit 13 can include a counter circuit 21, an output control circuit 23, and a counter control circuit 25. The counter circuit 21 counts a clock signal SCLK. The output control circuit 23 is configured to generate the PWM control signal SPWM in response to the count signal SCNT from the output of the counter circuit 21, and to control the outputting of the PWM control signal SPWM. The counter control circuit 25 stores a count value that determines a PWM waveform to be produced. The counter control circuit 25 compares this value with the count signal SCNT, and when the count signal SCNT becomes equal to the stored value, the counter control circuit 25 allows the outputting of the counter circuit 21 to the output control circuit 23 and clears the counter circuit 21. In response to this clear operation, the counter circuit 21 restarts the counting to form the next PWM waveform.

The PWM signal generation circuit 13 controls the operation of the counter circuit 21 in association with the first external trigger signal STRG1 and the first control signal SCTL1. Specifically, the start of the counter circuit 21 is associated with the transition of the first external trigger signal STRG1 and the first control signal SCTL1.

The first control circuit 31 is configured to generate the first control signal SCTL1 in response to the first external trigger signal STRG1 to control the PWM signal generation circuit 13 at the timing of start of the PWM control. The first control circuit 31 operates as a start control circuit to control the starting of the PWM control signal SPWM. Specifically, the start control circuit may be configured to operate to start the counter circuit 21 and the output control circuit 23. The stop control circuit may be configured to operate to stop both the counter circuit 21 and the output control circuit 23.

The PWM signal generation circuit 13 includes at least one of a first circuit 39, a second circuit 49, and a third circuit 59. The first, second, and third circuits 39, 49, and 59 enable various PWM controls.

The first circuit 39 is used in the PWM signal generation circuit 13, the operation of which is controlled by the first control circuit 31 at the timing of start of the PWM control and by the second control circuit 43 at the timing of end thereof. In the PWM signal generation circuit 13, the first circuit 39 controls the transition of the PWM control signal SPWM in response to the first and second control signals SCTL1 and SCTL2. The first control circuit 31 operates as a start control circuit, which receives the external trigger signal as an input signal to respond to its first transition alone, and specifically, the start control circuit does not respond to any subsequent waveform change of the input signal. The second control circuit 43 operates as a stop control circuit, which receives the external trigger signal as an input signal to respond to its first transition alone, and specifically, the stop control circuit does not respond to any subsequent waveform change of the input signal.

The second circuit 49 is used in the PWM signal generation circuit 13, the operation of which is controlled by the first and second control circuits 31 and 43 at the timing of start of the PWM control and by the third control circuit 33 at the timing of end thereof. In the PWM signal generation circuit 13, the second circuit 49 is configured to put the counter circuit 21 into a disabled state in the first period of the second control signal SCTL2 to disable the output of the counter circuit 21. The second control circuit 43 operates as an independent control circuit. The third control circuit 33 operates as a stop control circuit, which receives the external trigger signal as an input signal to respond to its first transition alone, and specifically, the stop control circuit does not respond to any subsequent waveform change of the input signal.

The third circuit 59 is used in the PWM signal generation circuit 13, the operation of which is controlled by the first and second control circuits 31 and 43 at the timing of start and by the third control circuit 33 at the timing of end. In the PWM signal generation circuit 13, the third circuit 59 is configured to put the output control circuit 23 into the disabled state in the first period of the signal from the second control circuit 43, which operates in response to the second external trigger signal STRG2. The second control circuit 43 is operable as an independent control circuit. The third control circuit 33 operates as a stop control circuit, which receives the external trigger signal as an input signal to respond to its first transition alone, and specifically, the stop control circuit does not respond to any subsequent waveform change of the input signal.

When the PWM signal generation circuit 13 uses the first circuit 39, the counter circuit 21 operates in response to the first control signal SCTL1 from the first control circuit 31. When the PWM signal generation circuit 13 uses the second circuit 49, the counter circuit 21 operates in response to the first and second control signals SCTL1 and SCTL2. Specifically, the counter circuit 21 starts to operate in accordance with to the reception of the operation permission and the release of the operation prohibition which the first and second control signals SCTL1 and SCTL2 indicate, respectively. When the PWM signal generation circuit 13 uses the third circuit 59, the output control circuit 23 operates in response to the first and second control signals SCTL1 and SCTL2. Specifically, the output control circuit 23 starts to operate in accordance with the reception of the operation permission and the release of the operation prohibition which the first and second control signals SCTL1 and SCTL2 indicate, respectively.

Specifically, the PWM signal generation circuit 13 may include a first circuit 39. The PWM signal generation circuit 13 may also include a second circuit 49. Further, the PWM signal generation circuit 13 may include a third circuit 59. The PWM signal generation circuit 13 may be provided with the first and second circuits 39 and 49. The PWM signal generation circuit 13 may be provided with the second and third circuits 49 and 59. The PWM signal generation circuit 13 may be provided with the first and third circuits 39 and 59. The PWM signal generation circuit 13 may be provided with the first, second, and third circuits 39, 49, and 59.

The PWM signal generation circuit 13 may include a selection circuit 60 that selects the first, second, and third circuits 39, 49, and 59 so as to enable any one of them.

The second control circuit 43 generates a second control signal SCTL2 in response to the second external trigger signal STRG2 to control the PWM signal generation circuit 13 at either the timing of end or start of the PWM control. Further, the third control circuit 33 is configured to generate the third control signal SCTL3 in response to the third external trigger signal STRG3 at the timing of end of the PWM control to control the PWM signal generation circuit 13.

Each of the first, second, and third circuits 39, 49, and 59 will be described below with reference to FIGS. 2 to 7.

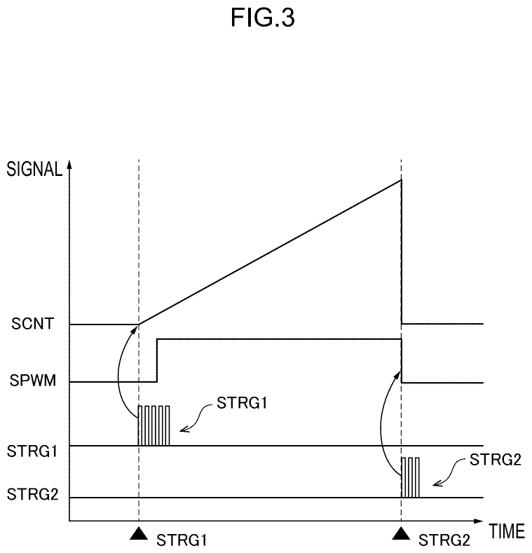

FIG. 2 is a schematic diagram illustrating an exemplary PWM circuit. FIG. 3 is a diagram showing exemplary operating waveforms of major nodes in the exemplary PWM circuit shown in FIG. 2.

As shown in FIG. 2, in the PWM circuit 11b, the first and third control circuits 31 and 33 are configured to receive the first and third external trigger signals STRG1 and STRG3 from the external trigger circuit 12b, respectively. The second and fourth control circuits 43 and 41 are configured to receive the second and fourth external trigger signals STRG2 and STRG4 from the external trigger circuit 12d, respectively. The fifth control circuit 53 is configured to receive a fifth external trigger signal STRG5 from the external trigger circuit 12c. The first and fourth control circuits 31 and 41 can operate as a start control circuit. The second and third control circuits 43 and 33 can operate as a stop control circuit. The fifth control circuit 53 can operate as an independent control circuit.

In the exemplary PWM circuit 11b, the first and second control circuits 31 and 43 are put into the ENABLE state, while the third, fourth, and fifth control circuits 31, 33, and 41 are put into the DISABLE state. In accordance with this configuration, the PWM signal generation circuit 13 uses the first control circuit 31 at the start of the period of the PWM control, and uses the second control circuit 43 at the end of the period of the PWM control.

The first control circuit 31 operates as the start control circuit, and the start control circuit receives the external trigger signal STRG1 as an input signal to respond to its first transition alone (either rising or falling edge) and, specifically, the start control circuit does not respond to any subsequent waveform change of the input signal. This operation mode can be initialized, for example, in response to trigger signals STRG5/STRG4. The first control circuit 31 thus initialized can again operate as a start control circuit, which receives the external trigger signal STRG2 as an input signal to respond to its first transition alone, and specifically, the start control circuit does not respond to any subsequent waveform change of the input signal.

The second control circuit 43 operates as a stop control circuit, which receives the external trigger signal STRG2 as an input signal to respond to its first transition alone (either rising or falling edge), and specifically, the stop control circuit does not respond to the subsequent waveform change of the input signal. This operation mode can be initialized, for example, in response to the trigger signal STRG1. The second control circuit 43 thus initialized can again operate as the stop control circuit, which receives the external trigger signal STRG2 as an input signal to respond to its first transition alone, and specifically, the stop control circuit does not respond to any subsequent waveform change of the input signal.

The exemplary PWM circuit 11b may be provided with the second control circuit 43, which works as the stop control circuit, and the second control circuit 43 is configured to receive the second external trigger signal STRG2 and control the PWM signal generation circuit 13 at the timing of end.

In the exemplary PWM circuit 11b, the PWM signal generation circuit 13 may be provided with the first circuit 39. The second external trigger signal STRG2 is used to determine the operation that the second control circuit 43 performs at the timing of the end, an in that case, the second control circuit 43 generates the second control signal SCTL2 in response to the second external trigger signal STRG2. The operation of the first circuit 39 allows the PWM signal generation circuit 13 to cause the PWM control signal SPWM to transition in response to the second control signal SCTL2 at the timing of the end. At the timing of the start, the PWM signal generation circuit 13 can operate to cause the PWM control signal SPWM to transition in response to the first control signal SCTL1. The first circuit 39 enables the PWM signal generation circuit 13 to control the transition of the PWM control signal SPWM in response to the first and second control signals SCTL1 and SCTL2.

In the exemplary PWM signal generation circuit 13, the first circuit 39 enables the counter circuit 21 and the output control circuit 23 to operate in response to the first control signal SCTL1 from the first control circuit 31. The PWM signal generation circuit 13 starts the period of the PWM control signal SPWM in response to the output signal of the counter circuit 21.

Referring to FIGS. 2 and 3, when the first control circuit 31 receives the first external trigger signal STRG1, the first control circuit 31 operates as the start control circuit to respond to the first external trigger signal STRG1 at the first transition thereof, so that the first control circuit 31 generates the first control signal SCTL1, which causes the counter circuit 21 of the PWM signal generation circuit 13 to start to operate. Further, when the second control circuit 43 receives the second external trigger signal STRG2, the second control circuit 43 operates as the stop control circuit to respond to the second external trigger signal STRG2 at the first transition thereof. The second control signal SCTL2 stops the operation of the counter circuit 21 of the PWM signal generation circuit 13. Such a signal delivery is made possible by the first circuit 39.

At the start of the period of the PWM control, if the first external trigger signal STRG1 includes a chattering waveform or component, as shown in FIG. 3, the PWM signal generation circuit 13 operates in response to the primary transition alone of the first control signal SCTL1. At the end of the PWM control period, if the second external trigger signal STRG2 also includes a chattering waveform or component, as shown in FIG. 3, the PWM signal generation circuit 13 operates in response to the primary transition alone of the second control signal SCTL2.

In the exemplary PWM circuit 11b, the PWM signal generation circuit 13 starts the period of the PWM control in response to the first control signal SCTL1 from the first control circuit 31. Further, the PWM signal generation circuit 13 terminates the period of the PWM control in response to the second control signal SCTL2 from the second control circuit 43.

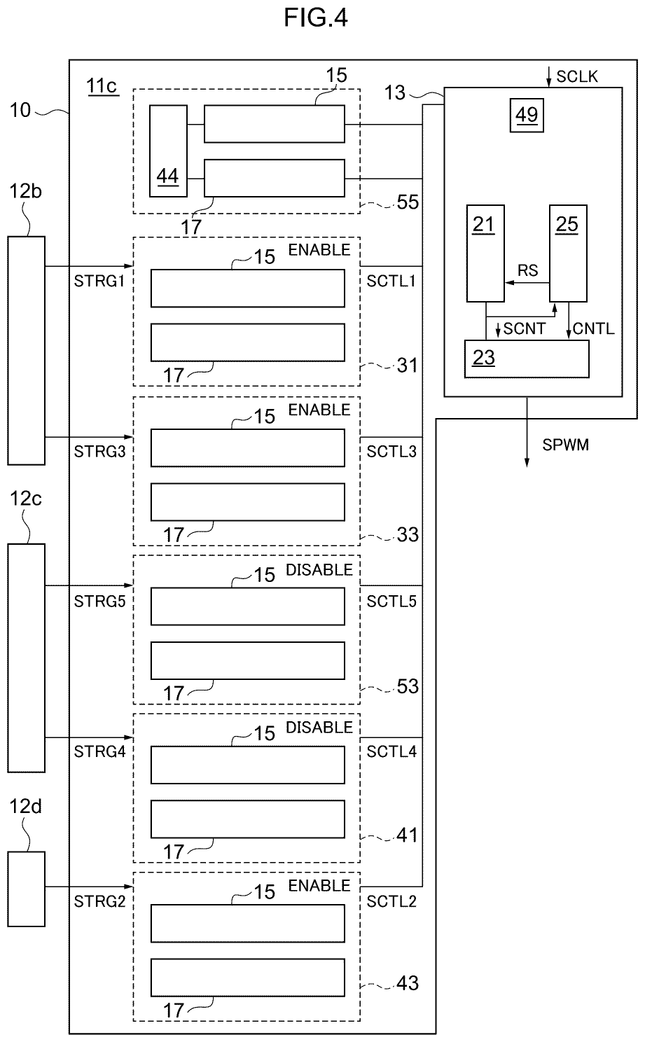

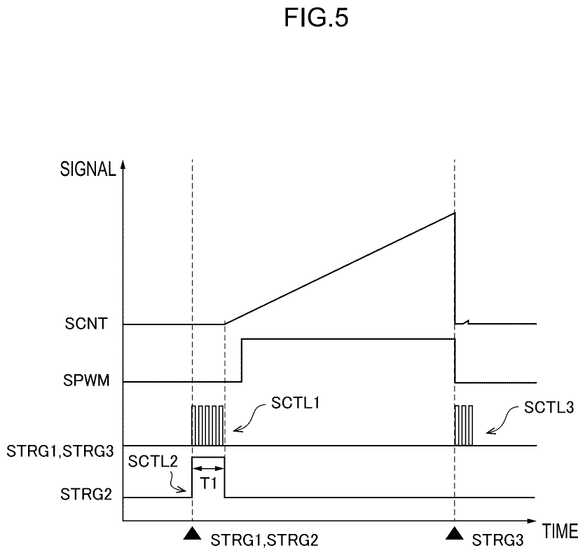

FIG. 4 is a schematic diagram illustrating an exemplary PWM circuit. FIG. 5 is a diagram showing exemplary operating waveforms of major nodes in the exemplary PWM circuit shown in FIG. 4.

As shown in FIG. 4, the first and third control circuits 31 and 33 are configured to receive the first and third external trigger signals STRG1 and STRG3 from the external trigger circuit 12b, respectively. The second control circuit 43 is configured to receive the second external trigger signal STRG2 from the external trigger circuit 12d. The fourth and fifth control circuits 41 and 53 are configured to receive fourth and fifth external trigger signals STRG4 and STRG5 from the external trigger circuit 12c, respectively. The first and fifth control circuits 31 and 53 can operate as a start control circuit, and the third and fifth control circuits 33 and 53 can operate as a stop control circuit. The second control circuit 43 can operate as an independent control circuit.

In the exemplary PWM circuit 11c, the first, second, and third control circuits 31, 33, and 43 are put into the ENABLE state, and the fourth and fifth control circuits 41 and 53 are put into the DISABLE state. In accordance with this configuration, the PWM signal generation circuit 13 uses the first and second control circuits 31 and 33 at the start of the PWM control period, and uses the third control circuit 43 at the end of the PWM control period.

The exemplary PWM circuit 11c may be provided with the third control circuit 33 acting as a stop control circuit, and the third control circuit 33 is configured to receive the third external trigger signal STRG3 to control the PWM signal generation circuit 13 at the timing of end.

In the exemplary PWM circuit 11c, the PWM signal generation circuit 13 may be provided with the second circuit 49. The second external trigger signal STRG2 is used to determine the operation that the second control circuit 43 performs at the timing of start, and in that case, the second circuit 49 may be configured to prevent the counter circuit 21 from outputting the count signal SCNT in the first period T1 of the second control signal SCTL2. This prevention can be performed by putting the counter circuit 21 into the disabled state of counting.

The third control circuit 33 operates as a stop control circuit, which receives the external trigger signal STRG3 as an input signal to respond to its first transition alone (either rising or falling edge), and specifically, the stop control circuit does not respond to any subsequent waveform change of the input signal. This operation mode can be initialized, for example, in response to the external trigger signal STRG1. The third control circuit 33 thus initialized can again operate as the stop control circuit, which receives the external trigger signal STRG3 as an input signal to respond to its first transition alone, and specifically, does not respond to any subsequent transitions of the input signal.

The second control circuit 43 operates as an independent control circuit, which receives the external trigger signal STRG2 as an input signal to respond to its first transition alone (either rising or falling edge), and specifically, the independent control circuit does not respond to any subsequent waveform change of the input signal. This operation mode can be initialized for the next start of the PWM control, for example, in response to the inputting of a trigger signal. The second control circuit 43 thus initialized can again operate as a control circuit that receives the external trigger signal STRG2 as an input signal to respond to its first transition alone and, specifically, does not respond to any subsequent waveform change of the input signal. The second control circuit 43 produces a window-shaped waveform, located in the first period T1, in accordance with the waveform of the external trigger signal STRG2.

However, the first control circuit 31 may operate as a start control circuit, which receives the external trigger signal STRG1 to respond to each transition (either rising or falling edge) thereof.

The exemplary PWM circuit 11c may be provided with the third control circuit 33 as the stop control circuit, and the second control circuit 43 is configured to receive the second external trigger signal STRG2 and control the PWM signal generation circuit 13 at the timing of start.

In the exemplary PWM circuit 11c, the PWM signal generation circuit 13 may be provided with the second circuit 49. The second control circuit 43 is used to prohibit the counter circuit 21 from outputting the count signal SCNT during a period in which chattering potentially occurs, for example, the first period T1. After the first period T1 ends, the output control circuit 23 produces the PWM control signal SPWM in response to the count signal SENT from the counter circuit 21. The exemplary second circuit 49 is configured to put the counter circuit 21 into a reset state during the first period T1 of the signal and to release the reset of the counter circuit 21 after the end of the first period T1. The second circuit 49 can operate to prevent, at the timing of start, the counter circuit 21 of the PWM signal generation circuit 13 from responding to incoming waveforms which enters the counter circuit 21 during the first period T1 of the window of the second control signal SCTL2. The first period T1 can be used to mask the effect of the first external trigger signal STRG1, which potentially includes a chattering waveform, on the PWM control. Accordingly, at the timing of start, the PWM signal generation circuit 13 does not immediately generate the PWM control signal SPWM in response to the reception of the first control signal SCTL1. The second circuit 49 enables the PWM signal generation circuit 13 to start the PWM control in response to the second control signal SCTL2 from the second control circuit 43. Further, at the timing of end, the third control circuit 33 generates the third control signal SCTL3 in response to the third external trigger signal STRG3 to control the PWM signal generation circuit 13. In response to the third control signal SCTL3, the PWM signal generation circuit 13 stops the counter circuit 21 and the output control circuit 23.

Specifically, the PWM circuit 11c starts the operation of the counter circuit 21, which follows the setting of the operation permission of the first control signal SCTL1 and the release of the operation prohibition of the second control signal SCTL2.

Referring to FIGS. 4 and 5, the second control circuit 43 receives the second external trigger signal STRG2 and, in response to this reception, generates the second control signal SCTL2. The second circuit 49 operates in response to the second control signal SCTL2 to prohibit the counter circuit 21 either from outputting the count signal SCNT to the output control circuit 23 or from operating.

At the start of the period of the PWM control signal SPWM, after the first period T1 of the second control signal SCTL2 ends, the PWM signal generation circuit 13 causes the PWM control signal SPWM to transition. Specifically, the PWM control signal SPWM transitions after the counter circuit 21 completes one cycle of counting.

In the exemplary PWM circuit 11c, the PWM signal generation circuit 13 starts the period of the PWM control in response to the end of the second control signal SCTL2 from the second control circuit 43. Specifically, the PWM control signal SPWM is changed after the counter circuit 21 completes one cycle of counting.

At the end of the period of the PWM control signal SPWM, the PWM signal generation circuit 13 responds to the third control signal SCTL3, which is produced from the first transition edge of the third external trigger signal STRG3 with chattering as shown in FIG. 5, to cause the PWM control signal SPWM to transition.

The PWM signal generation circuit 13 uses the second circuit 49 to prohibit the counter circuit 21 from outputting the count signal SCNT during the first period T1 of the signal from the second control circuit 43, which operates in response to the second external trigger signal STRG2. The first period T1 may be determined to have a period of time in which chattering, as shown in FIG. 5, may occur in the first external trigger signal STRG1 and the first control signal SCTL1.

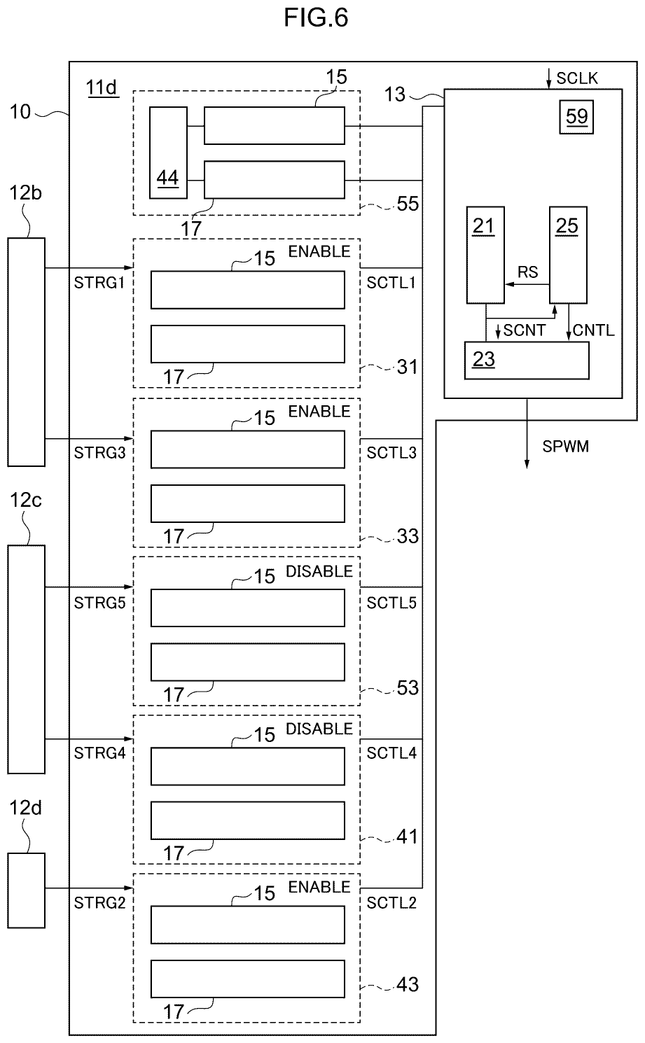

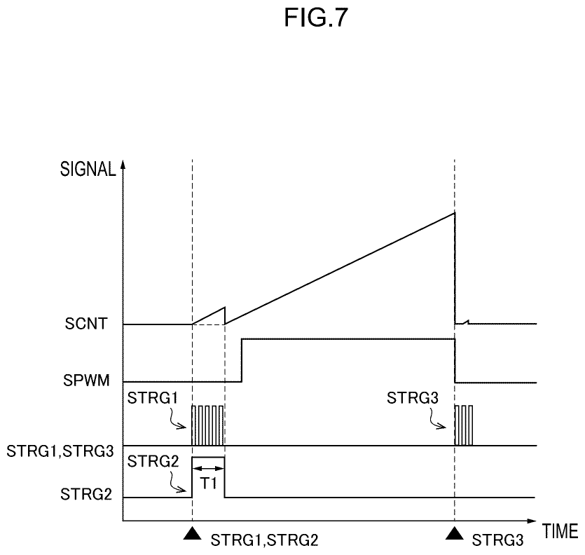

FIG. 6 is a schematic diagram illustrating an exemplary PWM circuit. FIG. 7 is a diagram showing operating waveforms of major nodes in the exemplary PWM circuit shown in FIG. 6.

As shown in FIG. 6, the first and third control circuits 31 and 33 are configured to receive the first and third external trigger signals STRG1 and STRG3 from the external trigger circuit 12b, respectively. The second control circuit 43 is configured to receive the second external trigger signal STRG2 from the external trigger circuit 12d. The fourth and fifth control circuits 41 and 53 are configured to receive the fourth and fifth external trigger signals STRG4 and STRG5 from the external trigger circuit 12c, respectively. The first and fifth control circuits 31 and 53 can operate as a start control circuit, and the third and fourth control circuits 33 and 41 can operate as a stop control circuit. The second control circuit 43 can operate as an independent control circuit.

In the exemplary PWM circuit 11d, the first, second, and third control circuits 31, 33, and 43 are put into the ENABLE state, and the fourth and fifth control circuits 41 and 53 are put into the DISABLE state. In accordance with this configuration, the PWM signal generation circuit 13 uses the first control circuit 31 to start the period of the PWM control signal SPWM, and uses the third control circuit 33 to terminate the period of the PWM control signal SPWM.

In the exemplary PWM circuit 11d, the PWM signal generation circuit 13 may be provided with the third circuit 59. The second external trigger signal STRG2 is used to determine the operation that the second control circuit 43 performs at the timing of start, snf in that case, the third circuit 59 is configured to prohibit the output control circuit 23 from outputting the signal SPWM in the first period of the window signal of the second control signal SCTL2.

The third control circuit 33 operates as a stop control circuit, which receives the external trigger signal STRG3 as an input signal to respond to its first transition alone (either rising or falling edge), and specifically, does not respond to any subsequent waveform change of the input signal. This operation is initialized for the next start of the PWM control, for example, in response to the inputting of a trigger signal. The third control circuit 33 thus initialized can operate again as the stop control circuit, which receives the external trigger signal STRG3 as an input signal to respond to its first transition alone, and specifically, does not respond to any subsequent waveform change of the input signal.

The second control circuit 43 operates as a single control circuit, which receives the external trigger signal STRG2 as an input signal to respond to its first transition alone (either rising or falling edge), and specifically, does not respond to any subsequent waveform change of the input signal. This operation can be initialized, for example, in response to the inputting of a trigger signal for the next termination of the PWM control. The second control circuit 43 thus initialized can again operate as a control circuit, which receives the external trigger signal STRG2 as an input signal to respond to its first transition alone, and specifically, does not respond to any subsequent waveform change of the input signal. The second control circuit 43 generates a waveform of the first period T1 in accordance with the waveform of the external trigger signal STRG2.

On the one hand, the first control circuit 31 works as a start control circuit, which receives the external trigger signal STRG1 as an input signal to respond to each first transition (either rising or falling edge).

The exemplary PWM circuit 11d may be provided with the third control circuit 33 as a stop control circuit, while the second control circuit 43 is configured to receive the second external trigger signal STRG2 and to control the PWM signal generation circuit 13 at the timing of start.

In the exemplary PWM circuit 11d, the PWM signal generation circuit 13 may be provided with the third circuit 59, and the second control circuit 43 is used to prohibit the output control circuit 23 from outputting the PWM control signal SPWM during a period, for example, the first period T1, in which chattering potentially occurs. After the first period T1 ends, the output control circuit 23 provides the PWM control signal SPWM in response to the count signal SCNT from the counter circuit 21. The exemplary third circuit 59 is configured to put, in the first period T1 of the signal, the output control circuit 23 into a disabled state in which the output of the output control circuit 23 is disabled, while the counter circuit 21 continues to operate in the first period T1, and is configured to put the output control circuit 23 into the output enabled state thereof after the end of the first period T1. Accordingly, at the timing of start, the third circuit 59 can prevent the output control circuit 23 of the PWM signal generation circuit 13 from responding to incoming signals from the counter circuit 21 in the first period T1 of the window of the second control signal SCTL2. The first external trigger signal STRG1, which potentially includes a chattering waveform, is masked in the first period T1 to remove the effect of the chattering on the PWM control. Accordingly, the PWM signal generation circuit 13 does not immediately generate the PWM control signal SPWM in response to the reception of the first control signal SCTL1 at the timing of start. The third circuit 59 enables the PWM signal generation circuit 13 to start the PWM control in response to the second control signal SCTL2 from the second control circuit 43. Further, the third control circuit 33 generates the third control signal SCTL3 in response to the third external trigger signal STRG3 at the timing of end to control the PWM signal generation circuit 13. The PWM signal generation circuit 13 stops the counter circuit 21 and the output control circuit 23 in response to the third control signal SCTL3.

Specifically, the PWM circuit 11c starts the operation of the output control circuit 23, which follows the setting of the operation permission of the first control signal SCTL1 and the release of the operation prohibition of the second control signal SCTL2.

Referring to FIGS. 6 and 7, the second control circuit 43 receives the second external trigger signal STRG2, and in response to this reception, generates the second control signal SCTL2. The third circuit 59 responds to the second control signal SCTL2 to prohibit the output control circuit 23 from outputting the count signal SCNT of the counter circuit 21.

At the start of the period of the PWM control signal SPWM, the PWM signal generation circuit 13 causes the PWM control signal SPWM to transition after the first period T1 of the second control signal SCTL2 ends. Specifically, after the output control circuit 23 becomes enabled, the PWM control signal SPWM transitions. After the first period T1 of the second control signal SCTL2 ends, the counter circuit 21 is cleared and starts counting again, and, specifically, after the counter circuit 21 completes one cycle of counting, the PWM control signal SPWM is changed.

At the end of the period of the PWM control signal SPWM, the PWM signal generation circuit 13 responds to the third control signal SCTL3, which is produced from the first transition edge of the third external trigger signal STRG3 with chattering as shown in FIG. 7, to cause the PWM control signal SPWM to transition.

The PWM signal generation circuit 13 uses the third circuit 59 to prohibit the output control circuit 23 from outputting a signal during the first period T1 of the signal from the second control circuit 43, which operates in response to the second external trigger signal STRG2. The first period T1 may be determined to have a period of time in which chattering, as shown in FIG. 7, may occur in the first external trigger signal STRG1 and the first control signal SCTL1.

Referring to FIG. 1 again, the PWM circuit 11 may include a sixth control circuit 55 which controls the PWM signal generation circuit 13 in response to the operation of the software 44.

Each of the first control circuit 31 to the sixth control circuit 55 can include an edge control circuit 15 and a level control circuit 17 which enable edge control and level control, respectively. The first control circuit 31 to the fifth control circuit 55 according to the present disclosure can be put into, for example, an edge control mode. The control circuits (31, 33, 41, 43, and 53) may provide, each of the edge and level control circuits 15 and 17 with a selecting circuit which exclusively enables the respective controlling operations.

The present disclosure relates to a technique to activate the PWM circuit 11, which is embedded in the microcomputer 10, in response to external trigger signals. The switching of the external trigger signals may generate chattering components, and it is required to reduce the influence of the chattering in the starting or stopping of the PWM circuit 11 thereon.

The present disclosure can provide the PWM circuit 11 that reduces the influence of the chattering.

Next, the technical background of the present embodiment will be described.

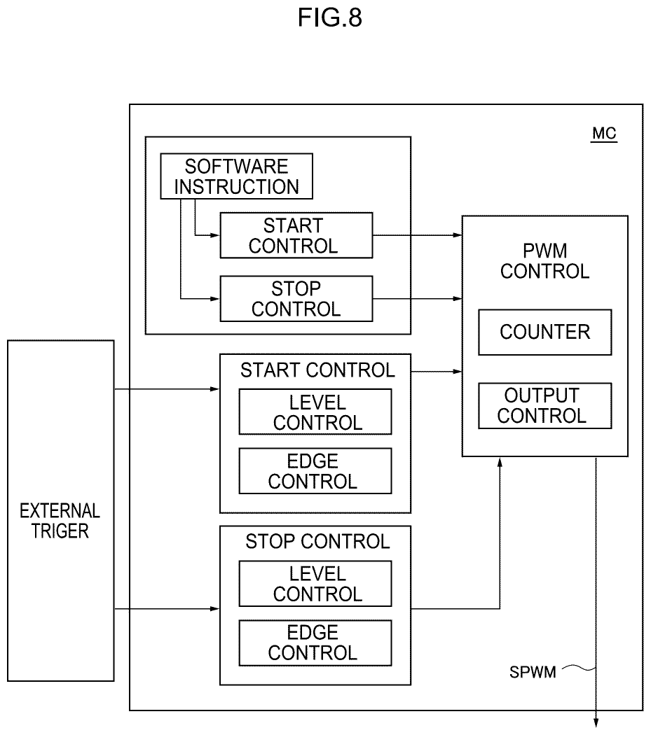

FIG. 8 is a schematic diagram showing a PWM circuit in a microcomputer MC, and circuit blocks related to the starting/stopping of the PWM circuit.

Referring to FIG. 8, the PWM circuit includes a counter circuit, a PWM control circuit which generates a PWM waveform determined according to the counting value of the counter circuit, a start control circuit which controls the starting of the PWM control, and a stop control circuit which controls the stopping of the PWM control.

Software instructions indicate a signal which can be generated by the central processing unit of the microcomputer MC. External trigger circuits are separate from the microcomputer MC, and generates their external trigger signals, which are supplied to the microcomputer. The PWM control circuit performs start and stop controls in response to the soft-command from the software instructions or the external trigger signals from the external trigger signals. Furthermore, the start control and stop control each have a level control function and an edge control function.

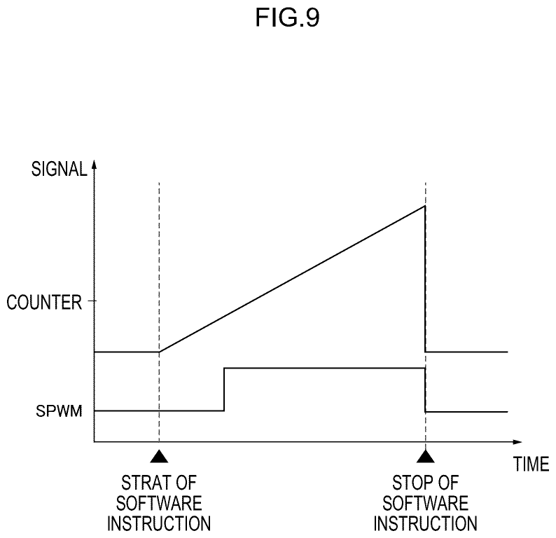

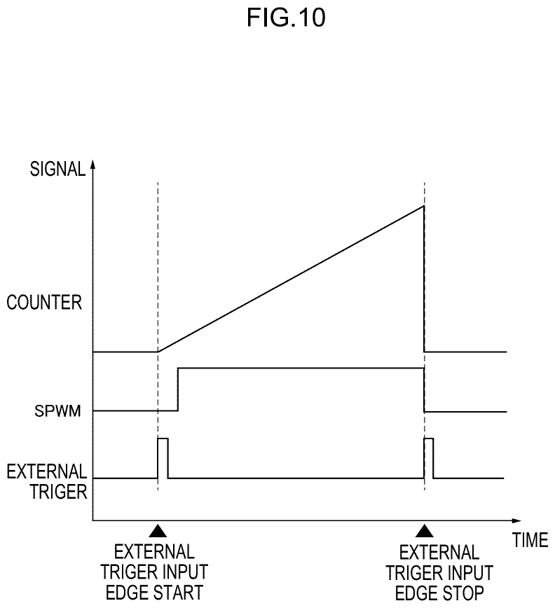

FIG. 9 shows operating waveforms in the start and stop controls, performed using software instructions, of the PWM control circuit. FIG. 10 shows operating waveforms in the edge control at the time of the start and stop controls, performed using an external trigger signal, of the PWM control circuit. Using the soft instructions causes no chattering.

The start/stop signals in performing the edge control are produced from external trigger signals.

In the operation that uses software instructions, the microcomputer MC processes a series of instructions, and converts the result of the central processing unit into a control signal, while in the operation that uses the edge control, an external trigger signal is converted into an internal signal. Accordingly, the control and internal signals, which indicate the same operation, cause the PWM control circuit to perform the same operation.

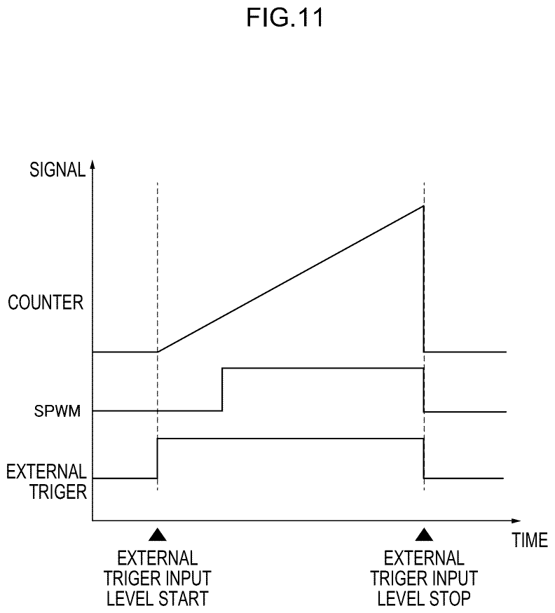

FIG. 11 shows operating waveforms in the level control, which is performed by the PWM control circuit, at the time of the start and stop controls. In the level control, the start/stop signals are produced from external trigger signals. In the circuit shown in FIG. 8 which uses the level control to perform the start/stop controls with the external trigger signals, the PWM control circuit operates in response to the signal maintained at the start level (“H” level in the figure) to start and operates in response to the signal maintained at the stop level (“L” level in the figure) to stop, as shown in FIG. 11.

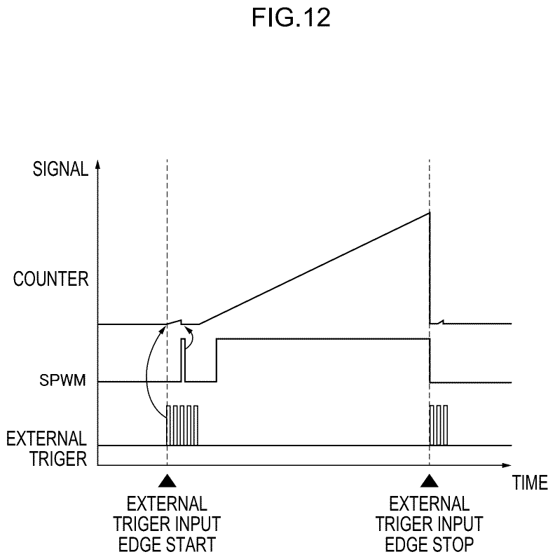

FIG. 12 shows operating waveforms in the edge control, which is performed by the PWM control circuit, at the time of the start and stop controls. In the circuit shown in FIG. 8 which uses the edge control to perform the start/stop controls with the external trigger signals, the external trigger signals may include chattering as shown in FIG. 12. When the PWM control circuit is subjected to the chattering, the occurrence of chattering may cause the PWM control circuit to generate ON/OFF levels changing repeatedly at the output thereof during the chattering, and the repeated ON/OFF levels may not allow the controlled circuit, connected to the output of the PWM control circuit, to operate appropriately.

In such cases, the following measures are applied so far.

### Measure 1

One of the start and stop controls is performed by an external trigger signal, and the other is performed by not the external trigger signal but software commands.

### Measure 2

In starting the PWM circuit, the start control is enabled and the stop control is disabled.
After the start control has been finished, the start control is disabled and the stop control is enabled.

### Measure 3

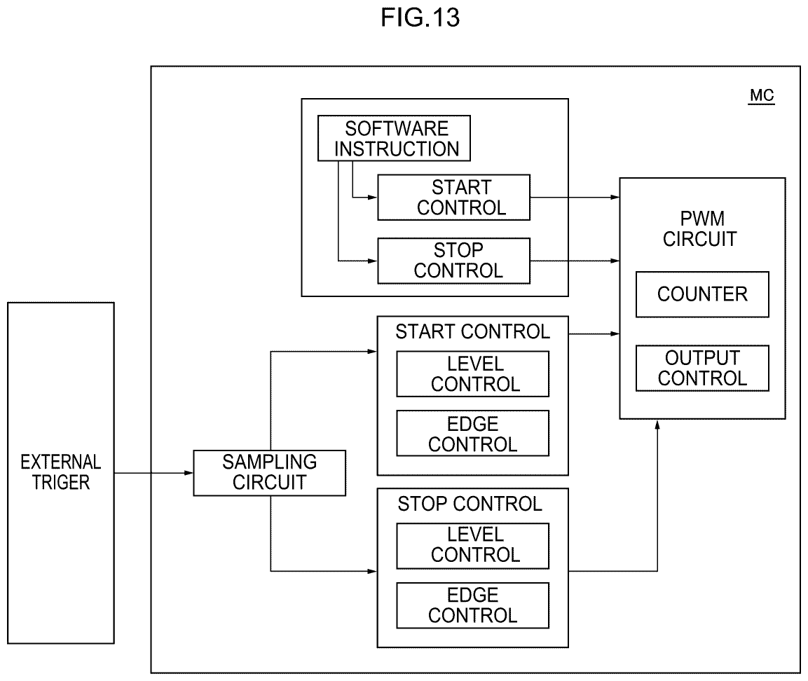

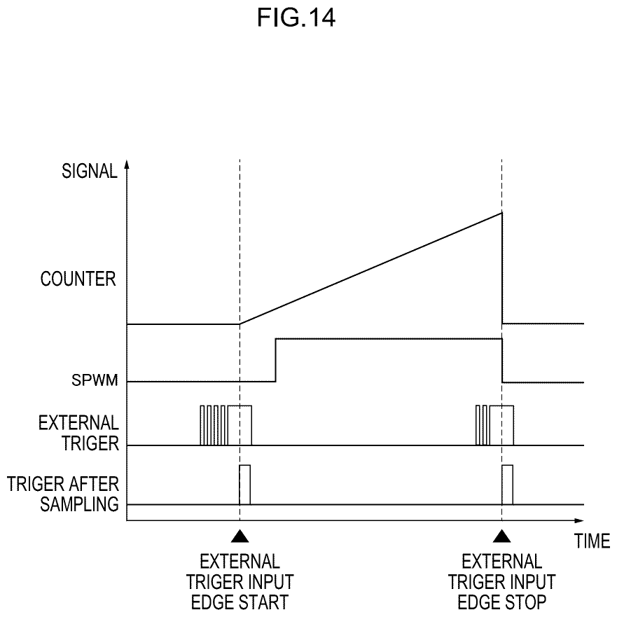

As shown in FIGS. 13 and 14, an external trigger is sampled to generate the sampled signal, and the sampled signal is received.

### Measure 4.

The start/stop controls are performed using the level control.

However, these measures have some issues.

Measures 1 and 2 requires the microcomputer MC to execute software instructions. In that case, one way is to cause the central processing unit thereof to start to control the PWM control circuit after the interruption of the processing of other controls. Another way is to wait for the completion of the processing of the other controls in the central processing unit without the interruption and thereafter, perform the start/stop controls of the PWM circuit, which delays the PWM control.

In measure 3, since the chattering is observed over a period of several milliseconds, the sampling period that has several milliseconds just after the reception of an external trigger signal allows the removal of the chattering. However, the sampling period prevents the PWM circuit from starting/stopping, thereby decreasing the responsiveness to the external trigger signal.

In measure 4, the PWM circuit repeats the ON/OFF levels thereof while chattering occurs.

As can be seen from the above disclosure, there is a problem with the starting/stopping the PWM circuit built into a microcomputer. The present disclosure can provide the PWM circuit that can reduce the influence of chattering. Further, the present disclosure shows that the PWM circuit can reduce the occurrence of the above-mentioned problems.

The present disclosure can be provided with various embodiments as shown below.

A PWM circuit of the first embodiment according to the present disclosure includes a PWM signal generation circuit including a counter circuit and an output control circuit, and configured to generate a PWM control signal; and multiple control circuits configured to control the PWM signal generation circuit at at least one of the timings of start and end of a PWM control, wherein the multiple control circuits include a first control circuit configured to generate a first control signal in response to a first external trigger signal and to control the PWM signal generation circuit at the timing of start of the PWM control, wherein the multiple control circuits include a second control circuit configured to generate a second control signal in response to a second external trigger signal, and to control the PWM signal generation circuit at one of the timings of start and end of the PWM control, wherein the PWM signal generation circuit is configured to start the operation of the counter circuit in association with the first control signal from the first control circuit, wherein the PWM signal generation circuit includes at least one of first, second, and third circuits as follows: the first circuit is configured to perform the PWM control in response to the first control signal from the first control circuit and the second control signal from the second control circuit when the first control circuit is configured to control the operation of the PWM signal generation circuit at the timing of start of the PWM control and the second control circuit is configured to determine the operation of the PWM signal generation circuit at the timing of end of the PWM control; the second circuit is configured to put the counter circuit into an output disabled state in a first period of the second control signal from the second control circuit when the first and second control circuits are configured to control the operation of the PWM signal generation circuit at the timing of start of the PWM control, a third control circuit of the multiple control circuits determines the operation of the PWM signal generation circuit at the timing of end of the PWM control, and the third control circuit is different from the first and second control circuits; and the third circuit is configured to put the output control circuit into an output disabled state in the first period of the second control signal from the second control circuit when the first and second control circuits are configured to control the operation of the PWM signal generation circuit at the timing of start of the PWM control and the third control circuit is configured to control the operation of the PWM signal generation circuit at the timing of end of the PWM control.

In the PWM circuit of the second embodiment according to the first embodiment of the present disclosure, the PWM signal generation circuit is provided with the first circuit, the multiple control circuits includes a third control circuit operable in response to a third external trigger signal, and the operation of the PWM signal generation circuit at the timing of end of the PWM control is determined by the third external trigger signal, the multiple control circuits further includes a fourth control circuit operable in response to a fourth external trigger signal, and the operation of the PWM signal generation circuit at the timing of start of the PWM control is determined by the fourth external trigger signal, the third control circuit is set to be disabled, the fourth control circuit are set to be disabled, and the first and third external trigger signals are provided by a first trigger circuit, and the second and fourth external trigger signals are provided by a second trigger circuit different from the first trigger circuit.

In the PWM circuit of the third embodiment according to the first or second embodiment of the present disclosure, the PWM signal generation circuit may be provided with the second circuit, the second circuit may be configure to put the output control circuit into the output disabled state, and the third control circuit may be operable in response to a third external trigger signal. The first and third external trigger signals may be provided by a first trigger circuit, and the second external trigger signal may be provided by a second trigger circuit different from the first trigger circuit.

In the PWM circuit of the fourth embodiment according to the first, second, or third embodiment according to the present disclosure, the PWM signal generation circuit may be provided with the third circuit, the third circuit may be configure to put the counter circuit into the output disabled state, and the third control circuit may be operable in response to a third external trigger signal. The first and third external trigger signals may be provided by a first trigger circuit, and the second external trigger signal may be provided by a second trigger circuit different from the first trigger circuit.

In the PWM circuit on the fifth embodiment according to any one of the first to fourth embodiments according to the present disclosure, each of the first and second control circuits may include an edge control circuit and a level control circuit, and the edge and level control circuits may be configured to enable edge and level controls, respectively.

In the PWM circuit of the sixth embodiment according to the fifth embodiment of the present disclosure, each of the first and second control circuits may be put into the edge control.

In the PWM circuit of the seventh embodiment according to any one of the first to sixth embodiments of the present disclosure, the first external trigger signal may include a chattering component.

In the PWM circuit of the eighth embodiment according to any one of the first to seventh embodiments of the present disclosure, the counter circuit is configured to count a clock signal to produce a count signal and output the count signal in response to the second external trigger signal, and the output control circuit is configured to provide the PWM control signal in response to the count signal.

In the PWM circuit of the ninth embodiment according to any one of the first to eighth embodiments of the present disclosure, the counter circuit is configured to count a clock signal to produce a count signal, the counter circuit is configured to control the outputting of the count signal in response to the second external trigger signal, and the output control circuit is configured to provide the PWM control signal in response to the count signal.

In the PWM circuit of the tenth embodiment according to any one of the first to ninth embodiments of the present disclosure, the counter circuit may be configured to count a clock signal to produce a count signal, the PWM signal generation circuit may further include a counter control circuit, and the counter control circuit stores a count value, and the counter control circuit may be configured to compare the count signal with the count value and to control the output control circuit based on a comparison of the count signal with the count value.

In the PWM circuit of the 11th embodiment according to any one of the first to tenth embodiments of the present disclosure, the first control circuit may be configured to receive the first external trigger signal as an input signal to generate the first control signal in response to a first transition of the input signal without responding to the subsequent change of the input signal.

In the PWM circuit of the 12th embodiment according to any one of the first to 11th embodiments of the present disclosure, the second control circuit may be configured to control the PWM signal generation circuit to put at least one of the output control circuit and the counter circuit into the output disabled state.

In the PWM circuit of the 13th embodiment according to the 12th embodiment of the present disclosure, the second control circuit may be configured to control the PWM signal generation circuit to put the output control circuit into the output disabled state.

In the PWM circuit of the 14th embodiment according to the 12th embodiment of the present disclosure, the second control circuit may be configured to control the PWM signal generation circuit to put the counter circuit into the output disabled state.

A PWM circuit of the 15th embodiment according to the present disclosure includes: a PWM signal generation circuit including a counter circuit and configured to generate a PWM control signal; and multiple control circuits configured to control the PWM signal generation circuit, wherein the multiple control circuits may include a first control circuit, wherein the first control circuit may be configured to receive a first external trigger signal as an input signal to generate a first control signal in response to a first transition of the input signal without responding to the subsequent change of the input signal, and wherein the PWM signal generation circuit may be configured to start a PWM control in response to the first control signal and to allow the counter circuit to operate in response to the first control signal.

A PWM circuit of the 16th embodiment according to the present disclosure includes: a PWM signal generation circuit configured to generate a PWM control signal, and including a counter circuit and an output control circuit; and multiple control circuits configured to control the PWM signal generation circuit, wherein the multiple control circuits include a first control circuit and a second control circuit, wherein the first control circuit is configured to generate a first control signal in response to a first external trigger signal, wherein the second control circuit is configured to generate a second control signal in response to a second external trigger signal, wherein the PWM signal generation circuit is configured to start a PWM control in response to the first and second control signals, and wherein the PWM signal generation circuit is operable in response to the second control signal to put at least one of the output control circuit and the counter circuit into an output disabled state during a first period of the second control signal and to provide the PWM control signal after the first period of the second control signal.

In the PWM circuit of the 17th embodiment according to the 16th embodiment of the present disclosure, the output control circuit may be put into the output disabled state.

In the PWM circuit of the 18th embodiment according to the 16th embodiment of the present disclosure, the counter circuit may be put into the output disabled state.

An apparatus of the 19th embodiment according to the present disclosure includes: a PWM circuit according to any one of the first to 18th embodiments, the PWM circuit being incorporated in a microcomputer; and one or more trigger circuits configured to being electrically coupled to the PWM circuit and to generate at least one of the first and second external trigger signal, the trigger circuits being outside the microcomputer.

An apparatus of the 20th embodiment according to the present disclosure includes: a PWM circuit according to any one of the first to 18th embodiments, the PWM circuit being incorporated in a microcomputer; and a device configured to being electrically coupled to the PWM circuit to operate in response to the PWM control signal, the device being outside the microcomputer.

The present disclosure is not limited to the disclosures described above, and can be implemented with various changes without departing from the spirit of the present disclosure. All of these are included in the technical idea of the present disclosure.

What is claimed is:

1. A PWM circuit including:
a PWM signal generation circuit configured to generate a PWM control signal, and including a counter circuit and an output control circuit; and
multiple control circuits configured to control the PWM signal generation circuit at at least one of the timings of start and end of a PWM control,
wherein the multiple control circuits include a first control circuit configured to generate a first control signal in response to a first external trigger signal and to control the PWM signal generation circuit at the timing of start of the PWM control,
wherein the multiple control circuits include a second control circuit configured to generate a second control signal in response to a second external trigger signal and to control the PWM signal generation circuit at one of the timings of start and end of the PWM control,
wherein the PWM signal generation circuit is configured to start the operation of the counter circuit in association with the first control signal,
wherein the PWM signal generation circuit includes at least one of first, second, and third circuits as follows:
the first circuit is configured to perform the PWM control in response to the first and second control signals when the first control circuit is configured to control the operation of the PWM signal generation circuit at the timing of start of the PWM control and the second control circuit is configured to determine the operation of the PWM signal generation circuit at the timing of end of the PWM control;
the second circuit is configured to put the counter circuit into an output disabled state in a first period of the second control signal from the second control circuit when the first and second control circuits are configured to control the operation of the PWM signal generation circuit at the timing of start of the PWM control, a third control circuit of the multiple control circuits determines the operation of the PWM signal generation circuit at the timing of end of the PWM control, and the third control circuit is different from the first and second control circuits; and
the third circuit is configured to put the output control circuit into an output disabled state in the first period of the second control signal from the second control circuit when the first and second control circuits are configured to control the operation of the PWM signal generation circuit at the timing of start of the PWM control and the third control circuit is configured to control the operation of the PWM signal generation circuit at the timing of end of the PWM control.

2. The PWM circuit according to claim 1,
wherein the PWM signal generation circuit is provided with the first circuit,
wherein the multiple control circuits includes a third control circuit operable in response to a third external trigger signal, and the operation of the PWM signal generation circuit at the timing of end of the PWM control is determined by the third external trigger signal,
wherein the multiple control circuits further includes a fourth control circuit operable in response to a fourth external trigger signal, and the operation of the PWM signal generation circuit at the timing of start of the PWM control is determined by the fourth external trigger signal,
wherein the third control circuit is set to be disabled,
wherein the fourth control circuit are set to be disabled, and
wherein the first and third external trigger signals are provided by a first trigger circuit, and the second and fourth external trigger signals are provided by a second trigger circuit different from the first trigger circuit.

3. The PWM circuit according to claim 1,
wherein the PWM signal generation circuit is provided with the second circuit, and the second circuit is configured to put the output control circuit into the output disabled state,
wherein the third control circuit is operable in response to a third external trigger signal, and
wherein the first and third external trigger signals are provided by a first trigger circuit, and the second external trigger signal is provided by a second trigger circuit different from the first trigger circuit.

4. The PWM circuit according to claim 1,
wherein the PWM signal generation circuit is provided with the third circuit, and the third circuit is configured to put the counter circuit into the output disabled state,
wherein the third control circuit is operable in response to a third external trigger signal, and
wherein the first and third external trigger signals are provided by a first trigger circuit, and the second external trigger signal is provided by a second trigger circuit different from the first trigger circuit.

5. The PWM circuit according to claim 1,
wherein each of the first and second control circuits includes an edge control circuit and a level control circuit, and the edge and level control circuits are configured to enable edge and level controls, respectively.

6. The PWM circuit according to claim 5,
wherein each of the first and second control circuits is put into the edge control.

7. The PWM circuit according to claim 1,
wherein the first external trigger signal includes a chattering component.

8. The PWM circuit according to claim 1,
wherein the counter circuit is configured to count a clock signal to produce a count signal and output the count signal in response to the second external trigger signal, and
wherein the output control circuit is configured to provide the PWM control signal in response to the count signal.

9. The PWM circuit according to claim 1,
wherein the counter circuit is configured to count a clock signal to produce a count signal,
wherein the counter circuit is configured to control the outputting of the count signal in response to the second external trigger signal, and
wherein the output control circuit is configured to provide the PWM control signal in response to the count signal.

10. The PWM circuit according to claim 1,
wherein the counter circuit is configured to count a clock signal to produce a count signal,
wherein the PWM signal generation circuit further includes a counter control circuit, and the counter control circuit stores a count value, and
wherein the counter control circuit is configured to compare the count signal with the count value and control the output control circuit based on a comparison of the count signal with the count value.

11. The PWM circuit according to claim 1,
wherein the first control circuit is configured to receive the first external trigger signal as an input signal to generate the first control signal in response to a first transition of the input signal without responding to the subsequent change of the input signal.

12. The PWM circuit according to claim 1,
wherein the second control circuit is configured to control the PWM signal generation circuit to put at least one of the output control circuit and the counter circuit into the output disabled state.

13. The PWM circuit according to claim 12,
wherein the second control circuit is configured to control the PWM signal generation circuit to put the output control circuit into the output disabled state.

14. The PWM circuit according to claim 12,
wherein the second control circuit is configured to control the PWM signal generation circuit to put the counter circuit into the output disabled state.

15. A PWM circuit including:
a PWM signal generation circuit including a counter circuit, and configured to generate a PWM control signal; and
multiple control circuits configured to control the PWM signal generation circuit,
wherein the multiple control circuits include a first control circuit, the first control circuit is configured to receive a first external trigger signal as an input signal to generate a first control signal in response to a first transition of the input signal without responding to the subsequent change of the input signal, and
wherein the PWM signal generation circuit is configured to start a PWM control in response to the first control signal and allow the counter circuit to operate in response to the first control signal.

16. A PWM circuit including:
a PWM signal generation circuit configured to generate a PWM control signal, and including a counter circuit and an output control circuit; and
multiple control circuits configured to control the PWM signal generation circuit,
wherein the multiple control circuits include a first control circuit and a second control circuit,
wherein the first control circuit is configured to generate a first control signal in response to a first external trigger signal,
wherein the second control circuit is configured to generate a second control signal in response to a second external trigger signal,
wherein the PWM signal generation circuit is configured to start a PWM control in response to the first and second control signals, and
wherein the PWM signal generation circuit is operable in response to the second control signal to put at least one of the output control circuit and the counter circuit into an output disabled state during a first period of the second control signal and to provide the PWM control signal after the first period of the second control signal.

17. The PWM circuit according to claim 16,
wherein the output control circuit is put into the output disabled state.

18. The PWM circuit according to claim 16,
wherein the counter circuit is put into the output disabled state.

19. An apparatus including:
a PWM circuit according to claim 1, the PWM circuit being incorporated in a microcomputer; and
one or more trigger circuits configured to being electrically coupled to the PWM circuit and to generate at least one of the first and second external trigger signal, the trigger circuits being outside the microcomputer.

20. An apparatus including:
a PWM circuit according to claim 1, the PWM circuit being incorporated in a microcomputer; and
a device configured to being electrically coupled to the PWM circuit to operate in response to the PWM control signal, the device being outside the microcomputer.
